(19) United States
(12) Patent Application Publication
(10) Pub. No.: US 2006/0057417 A1
(43) Pub. Date: Mar. 16, 2006

(54) Steel sheet plated by hot dipping with alloyed zinc with excellent adhesion and process for producing the same

(75) Inventors: Masahiko Tada, Tokyo (JP); Yoichi Tobiyama, Tokyo (JP); Kazuaki Kyono, Tokyo (JP); Noriko Makiishi, Tokyo (JP); Hisato Noro, Tokyo (JP)

Correspondence Address: FRISHAUF, HOLTZ, GOODMAN & CHICK, PC, 220 Fifth Avenue, 16TH Floor, NEW YORK, NY, 10001-7708, US

(73) Assignee: JFE STEEL CORPORATION, Tokyo (JP)

(21) Appl. No.: 10/527,182

(22) PCT Filed: Feb. 5, 2004
(86) PCT No.: PCT/JP04/01209

§ 371 Date: Apr. 29, 2005

(30) Foreign Application Priority Data
Feb. 10, 2003 (JP) 2003-032321
Feb. 10, 2003 (JP) 2003-032311
Feb. 10, 2003 (JP) 2003-032500
Jan. 21, 2004 (JP) 2004-01369

(51) Int. Cl. H05K 3/38; C25D 5/10

(52) U.S. Cl. 428/612; 428/659; 428/939

(57) ABSTRACT

The present invention provides a galvannealed steel sheet excellent in the adhesion with a base steel sheet and a manufacturing method thereof. The galvannealed steel sheet according to the invention has, in an interface between a galvannealed layer and the base steel sheet thereon the galvannealed layer is formed, an irregularity that has a depth of 10 nm or more at a pitch of 0.5 μm or less at least one per 5 μm of a length of the interface.

### TECHNICAL FIELD

The present invention relates to a galvannealed steel sheet excellent in the coating adhesion to a base steel sheet (mother material) and a method of manufacturing the same.

### BACKGROUND ART

In recent years, in the fields of automobiles, home electric appliances and construction materials, steel sheets that are surface treated to impart the rust resistance to base steel sheets are used. Among these, galvannealed steel sheets that can be cheaply manufactured and are excellent in the rust resistance after coating are in use. In the field of automobiles in particular, higher mechanical strength and lighter weight of the base steel sheets are in progress. There is an increasing tendency in the use of more galvannealed steel sheets that are rust resistant and high in the mechanical strength.

However, since an interface between a coating layer and a base steel sheet of a galvannealed steel sheet is brittle, for instance, when it is press-molded with a die, the coating layer peels, and the peeled coating layer sticks to the die to deteriorate product quality; accordingly, frequent cleaning of the die is necessary. In some cases, at a portion adhered with a secondary material, the coating layer peels and desired adhesive strength cannot be obtained. Alternatively, there is a problem in that when an automobile is running in winter, a coating layer comes to peel owing to chipping due to splattered stones or the like, and thereby desired rust resistance cannot be maintained.

In general, a galvannealed steel sheet, after a surface of a base steel sheet is degreased and/or acid washed to cleanse in a pretreatment process or, without applying the pretreatment, an oil content on a surface of the base steel sheet is burned and removed in a pre-heating furnace, is preheated in a weak acidic or reducing atmosphere, and undergoes a recrystallization annealing process in a reducing atmosphere. Thereafter, the base steel sheet is cooled in a reducing atmosphere to a temperature suitable for the coating, without exposing to air, dipped in a molten zinc coating bath in which a slight amount of Al (substantially 0.1 to 0.2 mass percent) is added, followed by controlling a coating thickness, and thereby a galvannealed steel sheet is manufactured.

A coating layer of the galvannealed steel sheet is made of an Fe—Zn alloy phase that is formed through mutual diffusion of Fe and Zn. In the neighborhood of an interface between the coating layer and the base steel sheet, an Fe—Zn alloy phase rich in a content of Fe is formed, and, as coming closer toward a surface of the coating layer, an Fe—Zn alloy phase poor in the content of Fe is formed. Since the Fe—Zn alloy phase that is formed in the neighborhood of an interface between the coating layer and the base steel sheet and rich in the content of Fe (for instance, Γ phase and Γ1 phase) is hard and brittle, when it is formed excessively thicker, the brittleness at the interface between the coating layer and the base steel sheet is enhanced. Furthermore, because the coating layer of the galvannealed steel sheet is made of an Fe—Zn alloy phase, there is a disadvantage in that since the adhesion of the coating layer at the interface between the coating layer and the base steel sheet is poor, peeling at the interface between the coating layer and the base steel sheet is likely to occur.

So far, in the galvannealed steel sheets, a method of improving the coating adhesion with the base steel sheet has been variously studied. For instance, in Patent Document 1, a technique in which in the case of ultra low carbon IF steel (Interstitial Free Steel) that contains 0.006 mass percent or less of carbon being used as a mother material, when Si, P and so on are properly added to steel, Zn in the coating layer is promoted to diffuse into a grain boundary of the mother material, and thereby the coating adhesion is improved is disclosed. However, in recent demands for higher mechanical strength, the ultra low carbon IF steel, being low in the mechanical strength, cannot attain satisfying performance. Furthermore, there is a problem in that in the case of a high strength steel sheet (for instance, a steel sheet in which carbon and other alloying elements are contained much in a mother material, thereby the tensile strength is made 440 MPa or more) being used, the technique according to the Patent Document 1 cannot necessarily obtain satisfying adhesiveness of the coating layer.

In Patent Document 2, it is disclosed that in the case of P-added steel in which 0.010 to 0.10 mass percent of P and 0.05 to 0.20 mass percent of Si are added to a mother material and Si≧P is satisfied being used, the adhesion of the coating can be improved. However, in the case of the technique being applied to steel sheets other than the P-added steel sheet, there is a problem in that satisfying adhesion of the coating layer cannot be necessarily obtained.

Furthermore, in Patent Document 3, a technique in which in the case of high strength retained austenite steel in which low carbon steel containing 0.05 to 0.25 mass percent of carbon is used as a mother material and proper amounts of Si and Al are added, when proper amounts of Ti, Nb and so on are added in the steel to. fix interstitial C, the coating interface strength can be improved is disclosed. However, this is a technique of the retained austenite steel, and there is a problem in that according to the technique described in Patent Document 3, in other high strength steel sheets that do not have a retained austenite phase, sufficient performance cannot be necessarily obtained.

Still furthermore, so far, as to a technique of improving the adhesion of an interface between a coating layer and a steel sheet of a galvannealed steel sheet, various studies have been conducted while paying attention to a shape of an interface between the coating layer and the base steel sheet. For instance, in Patent Documents 4 and 5, a technique in which the surface roughness of a surface of a steel sheet after a coating layer is removed therefrom is made 6.5 μm or more in terms of ten point height of irregularities Rz is disclosed. Furthermore, in Patent Document 6, a technique in which of P-added steel, the surface roughness Rz of a surface of the steel after a coating layer is removed therefrom is made to satisfy 12≧Rz≧0.0075·Sm+6.7 (where, Rz (μm): ten point height of irregularities, and Sm (μm): average distance between irregularities) is disclosed. However, the present inventors, after studying hard, found a new finding in that in a shape of an interface between the coating layer and the base steel sheet that contributes to the coating adhesion, fine irregularities that cannot be defined with the ten point height of irregularities Rz that is used in the existing finding are important, and thereby a galvannealed steel sheet very excellent in the coating adhesion to an extent that has not been so far found can be obtained.

Patent Document 1: Japanese Patent No. 3163986

Patent Document 2: Japanese Patent No. 2993404

Patent Document 3: JP-A-2001-335908

Patent Document 4: Japanese Patent No. 2638400

Patent Document 5: Japanese Patent No. 2932850

Patent Document 6: Japanese Patent No. 2976845

### DISCLOSURE OF INVENTION

The present invention intends to provide a galvannealed steel sheet that is remarkably excellent in the coating adhesion in comparison with an existing product, and a manufacturing method thereof.

A gist of the invention is as follows.

(I) A galvannealed steel sheet excellent in the coating adhesion, characterized in that in an interface between a galvannealed layer and a base steel sheet thereon the galvannealed layer is formed, an irregularity having a depth of 10 nm or more at a pitch of 0.5 μm or less is present at least one per 5 μm of a length of an interface.

(II) A galvannealed steel sheet excellent in the coating adhesion, characterized in that, as to a shape of a surface of a base steel sheet that is observed by peeling a galvannealed layer, a developed interfacial area ratio Sdr measured by use of a high-pass filter with a cut-off wavelength of 0.5 μm is 2.0 percent or more.

(III) The galvannealed steel sheet excellent in the coating adhesion according to the (I) or (II), characterized in that the base steel sheet contains, by mass percent, 0.25 percent or less of C, 0.03 to 2.0 percent of Si and 0.005 to 0.07 percent of P and has a composition satisfying the following equation (1).

Note
[C]+[P]≦[Si] (1)

Here, [C], [P] and [Si], respectively, mean contents (mass percent) of C, P and Si in the base steel sheet. (IV) The galvannealed steel sheet excellent in the coating adhesion according to the (III), characterized in that in a stage immediately before a coating layer is adhered to the base steel sheet, in order that Si contained in the base steel sheet may not be selectively oxidized on a surface, the base steel sheet is heat treated before the coating layer is adhered. (V) The galvannealed steel sheet excellent in the coating adhesion according to the (III) or (IV), characterized in that in base steel immediate below the interface an oxide of silicon is contained.

(VI) The galvannealed steel sheet excellent in the coating adhesion according to the (III), (IV) or (V), characterized in that the base steel sheet has a composition that further includes 5 percent or less of Mn, 0.01 percent or less of S and 0.08 percent or less of Al, by mass percent.

(VII) The galvannealed steel sheet excellent in the coating adhesion according to any one of the (III) through (VI), characterized in that the base steel sheet has a composition that further includes at least one kind selected from, by mass percent, 0.2 percent or less of Ti, 0.2 percent or less of Nb and 0.2 percent or less of V.

(VIII) A method of manufacturing a galvannealed steel sheet excellent in the coating adhesion, characterized in that a base steel sheet that contains, by mass percent, 0.25 percent or less of C, 0.03 to 2.0 percent of Si and 0.005 to 0.07 percent of P and has a composition satisfying the following equation (1) is heat treated so that Si in the steel may not be selectively surface oxidized, followed by cooling to a coating temperature in an atmosphere having an oxygen concentration of 0.005 volume percent or less, further followed by dipping the base steel sheet in a molten zinc coating bath to form a coating layer, still further followed by heating at a temperature rise speed of 20 degree centigrade/s or more to a temperature range of 460 to 600 degree centigrade and holding in the heating temperature range to apply a galvannealing process of the coating layer.

Note
[C]+[P]≦[Si] (1)

Here, [C], [P] and [Si], respectively, mean contents (mass percent) of C, P and Si in the base steel sheet. (IX) The method of manufacturing a galvannealed steel sheet excellent in the coating adhesion according to the (VIII), characterized in that the base steel sheet has a composition that further includes, by mass percent, 5 percent or less of Mn, 0.01 percent or less of S, and 0.08 percent or less of Al. (X) The method of manufacturing a galvannealed steel sheet excellent in the coating adhesion according to the (VIII) or (IX), characterized in that the base steel sheet has a composition that further includes at least one kind selected from, by mass percent, 0.2 percent or less of Ti, 0.2 percent or less of Nb and 0.2 percent or less of V and the temperature rise speed and a content of Si in the base steel sheet satisfy the following equation (2).

Note
ST≧3.25/[Si] (2)

Here, in the equation ST designates a temperature rise speed at a galvannealing process (degree centigrade/s) and [Si] designates a content (mass percent) of Si in the steel sheet.

### BRIEF DESCRIPTION OF THE DRAWINGS

FIG. 1 is a SEM photograph, in a galvannealed steel sheet according to the present invention, of a surface of a steel sheet after a coating layer is dissolved and removed.

FIG. 2 is a cross sectional SEM photograph of the galvannealed steel sheet according to the invention.

FIG. 3 is a diagram for explaining fine irregularities formed at an interface between a coating layer and a steel sheet in a galvannealed steel sheet according to the present invention.

FIG. 4 is a graph showing relationship between a ratio with which fine irregularities formed at an interface between the coating layer and the steel sheet occupy and the strength at the coating Steel interface.

FIG. 5 is a graph showing relationship between the developed interfacial area ratio Sdr and the strength of the coating Steel interface.

FIG. 6 is a graph showing, of a steel sheet containing at least one kind of Ti, Nb and V, an influence of a content of Si and a temperature rise speed at a galvannealing process on an area ratio of fine irregularities.

FIG. 7 is a diagram schematically showing a test sample that is used in tensile test for evaluating the coating adhesion 1.

FIG. 8 is a diagram schematically showing a test (bending-unbending test) for evaluating the coating adhesion 2.

FIG. 9 is a diagram schematically showing a test in which for evaluating the coating adhesion 4, a test sample is disposed in a bead die followed by pressing in a horseshoe shape.

FIGS. 10A and 10B each are a 3-D SEM image of a surface of the base Steel after the coating layer of the galvannealed steel sheet is removed, FIG. 10A showing a case of a material poor in the adhesion (comparative example), FIG. 10B showing a case of a material excellent in the adhesion (inventive example)

Descriptions of reference numerals in the respective drawings are as follows.
1: irregularity curve
2: base
3, 4: top
5: test sample
6: adhesive
7: spacer
8: arrow mark
9: test sample
10: recessed die
11: projected die
12: arrow mark
13: test sample
14: die
15: wrinkle suppressor
16: bead die
17: punch

### BEST MODE FOR CARRYING OUT THE INVENTION

In what follows, the present invention will be detailed.

A first invention relates to a galvannealed steel sheet excellent in the coating adhesion characterized in that in an interface between a galvannealed layer and a base steel sheet thereon the galvannealed layer is formed, an irregularity that has a depth of 10 nm or more at a pitch of 0.5 μm or less is present at least one per 5 μm of a length of the interface.

The present inventors, after an extensive study, found that when a continuous fine irregular portion is formed at an interface between a coating layer and a steel sheet, owing to an anchor effect thereof, the adhesion of an interface between the coating layer and the base steel sheet can be remarkably improved.

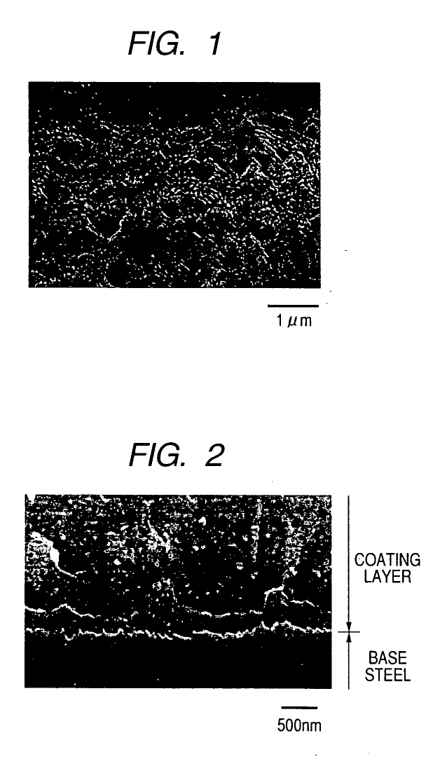

Each of FIGS. 1 and 2 is a SEM photograph that is taken when a continuous fine irregular portion at an interface between a coating layer and a base steel sheet that is one example of the invention is observed with a scanning electron microscope (SEM) FIG. 1 is a surface SEM photograph observed with a scanning electron microscope when a galvannealed layer is dissolved by applying ultrasonic in an alkaline aqueous solution to be removed and a surface of the base steel sheet at an interface between the coating layer and the base steel sheet is exposed. FIG. 2 is a sectional SEM photograph observed with a scanning electron microscope after a section of a galvannealed steel sheet is polished followed by etching with a 0.1 mass percent nital solution. In the irregular portion, the finer a pitch is, the more preferable, and the deeper a depth thereof is, the more preferable. The present inventors, as a result of study of relationship between the coating adhesion and the irregular state at the coating interface, found that an abundance of the irregularities that have a depth of 10 nm or more and exist with a pitch of 0.5 μm or less greatly correlates with the adhesive strength of the coating layer. In the irregular portion at an interface between the coating layer and the base steel sheet, by observing a section of the coating layer with a scanning electron microscope (SEM) or a transmission electron microscope (TEM), a pitch and a depth can be measured. A measuring method thereof will be shown below.

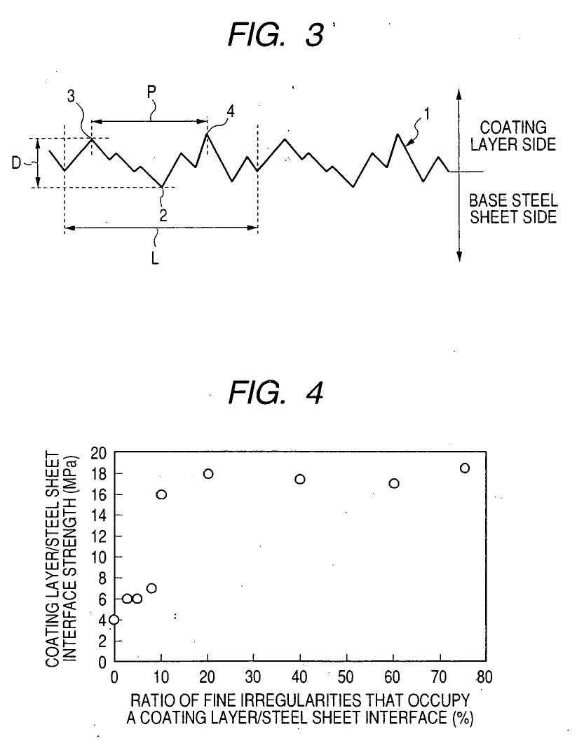

Measurements of the pitch and the depth are carried out as follows. That is, as shown in FIG. 3, with an irregular curve 1 that is at an interface and can be confirmed by the section observation, in the irregular curve 1, within a certain reference length L (for instance, 0.5 μm), a base 2 that is at a position lowest in height and two tops 3, 4 that are at positions highest in height on each of both sides of the base 2 are found out, a distance in a straight line measured in a length direction between these two tops 3, 4 is taken as a pitch P and a distance in a straight line measured in a height direction between the top 3 which is the lower one of the two tops 3, 4 and the base 2 is taken as a depth D. When with this measurement method a depth D is 10 nm or more in the reference length L (for instance, 0.5 μm), there is a fine irregularity that has a depth D of 10 nm or more at a pitch P of 0.5 μm or less.

However, in the invention, it is necessary that the irregularity having a depth of 10 nm or more at a pitch of 0.5 μm or less exists at least one per 5 μm of a length of interface. (Here, the length of interface means a distance in a straight line between two points on an interface in a cross section in a thickness direction.) This is because unless the irregularity exists at this ratio, it does not contribute to an improvement in the coating adhesion. The measurement of the irregularities is carried out as explained below. That is, a cross section of the coating layer having a length of 10 μm is divided into 20 of the reference length L (0.5 μm), 20 viewing fields are observed (Each of the viewing fields is measured at a magnification of at least 5000 times or more.), and, among these, the number of the viewing fields that have the fine irregularity having a depth D of 10 nm or more at a pitch P of 0.5 μm or less is counted. The measurement is repeated 5 times of an arbitrary cross section of the coating layer, and a percentage of the number of the viewing fields that have the fine irregularity to a total number of viewing fields (20×5=100) is taken as a ratio that the fine irregularities occupy. When the ratio is 10 percent or more, the above condition is considered satisfied.

In FIG. 4, relationship between thus measured ratio that the fine irregularities occupy and the strength at the coating Steel interface is shown. From FIG. 4, it is found that when the ratio that the fine irregularities occupy is 10 percent or more, the strength at the coating steel interface shows a high value. Here, the strength at the coating steel interface is a value obtained by carrying out a tensile test according to a method described in a later example (evaluation of the coating adhesion 1) followed by dividing the tensile strength by an adhered area.

From the above, in the invention, it is necessary that, in an interface between a galvannealed layer and a base steel sheet, an irregularity that has a depth of 10 nm or more at a pitch of 0.5 μm or less exists at least one per 5 μm of a length of the interface.

There is the directionality in the formation of the irregularities as shown in FIG. 1. However, a cross section in a direction where the irregularities exist most densely has only to satisfy the condition.

In the next place, a second invention will be explained.

The second invention relates to a galvannealed steel sheet excellent in the coating adhesion characterized in that, as to a surface shape of a base steel sheet observed after a galvannealed layer is removed, a developed interfacial area ratio Sdr measured by use of a high-pass filter with a cut-off wavelength of 0.5 pn is 2.0 percent or more.

The inventors paid attention to a developed interfacial area ratio Sdr as an index that can measure from a surface an extent of a continuous irregularity of interfaces of steel sheets shown in FIGS. 1 and 2. The developed interfacial area ratio expresses a ratio of an area of an actually irregular surface to an area where the irregularity does not exist in a measurement region and is a value expressed by the following equation.
Developed interfacial area ratio (Sdr)=(A−B)/B×100 (%)
A: a surface area of an actually irregular interface in a measurement region
B: an area of a plane where an irregularity does not exist in a measurement region

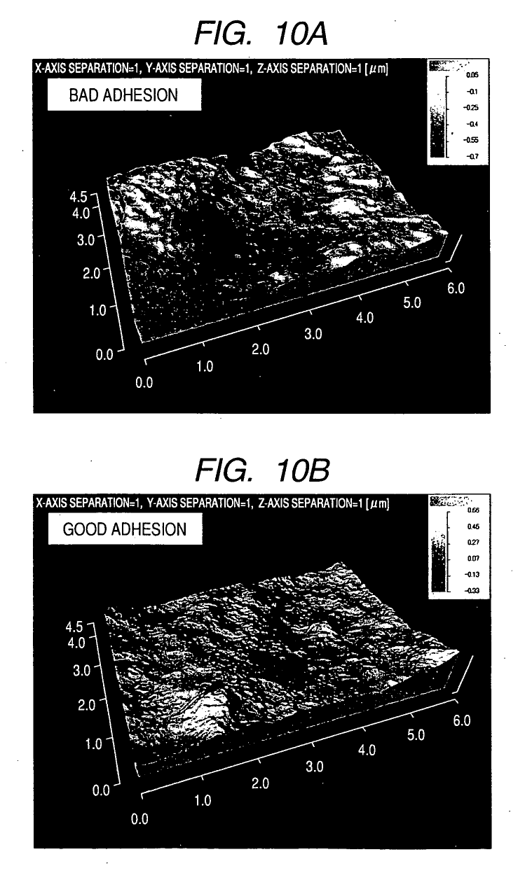

Accordingly, in an interface where the irregularity is large and a surface area is large, the Sdr takes a large value. A shape of the coating interface of the invention is formed of very fine irregularities; accordingly, quantitative evaluation was very difficult. However, it is considered to evaluate the fine irregularity by excellently exposing an interface followed by taking a SEM photograph at a high magnification, and thereby precisely calculating the evaluation index. That is, a surface of a base steel after a coating layer of a galvannealed steel sheetwas removed, after coating with several tens nanometers of Au so as not to affect on a surface composition, was measured with an electron beam three-dimensional surface roughness analyzer ERA-8800FE manufactured by Elionics Co., Ltd. followed by shape analysis, and thereby the developed interfacial area ratio Sdr was obtained. The shape analysis was carried out at an accelerating voltage of 15 kV, a viewing field that was magnified at a magnification of 10000 (viewing field area is 12 μm×9 μm) was taken in at a resolving power of 1200×900 points, followed by data processing. A value of the developed interfacial area ratio Sdr is obtained by measuring an arbitrarily selected area followed by averaging. In the calibration that was performed in a height direction with the device, a SHS thin film step standard (with three steps of 18, 88 and 450 nm) for contact stylus and optical surface roughness analyzer manufactured by VLSI Standard Inc. having traceable performance to the National Institute of Standards and Technology in the U.S. was used. Furthermore, a high pass filter having a cut-off wavelength of 0.5 μm was applied and an obtained value was supplied for calculation of three-dimensional shape parameter. The processing is important to remove an influence of undulation having a long period and thereby to evaluate the irregularities having targeted sizes. The cut-off wavelength as well has to be properly selected to a size of the irregularity that is to be evaluated. After studying variously, results processed with a high pass filter having a cut-off wavelength of 0.5 μm were found excellent in the correlation with the interface strength and in the reproducibility. Accordingly, under this condition, the data processing was carried out. Examples of measurement are shown in FIGS. 10A and 10B. FIG. 10A is a 3D-SEM image of a sample poor in the adhesion (comparative example) and FIG. 10B is a 3D-SEM image of a product excellent in the adhesion (inventive example), and values of the developed interfacial area ratio Sdr, respectively, were 1.7 percent for the comparative example and 2.5 percent for the inventive example. That is, there are distinct differences in the images and the Sdr values. On the other hand, the Ra in each of the images is 0.00531 μm for the comparative example and 0.00547 μm for the inventive example. That is, it is found that according to the Ra that is generally used, the difference cannot be quantified and the effectiveness of the evaluation method can be confirmed.

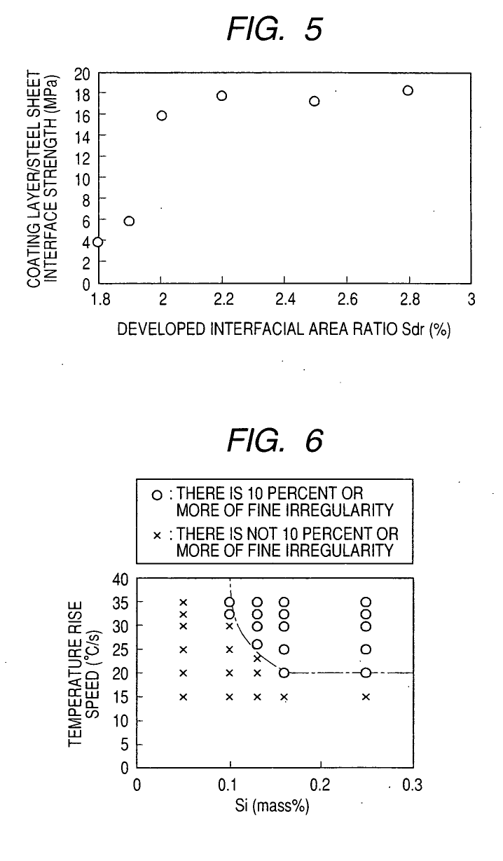

FIG. 5 is a graph showing relationship between values of the developed interfacial area ratio Sdr and the strengths of the coating interface at the interface between the coating layer and the base steel sheet. From FIG. 5, it is found that in the case of the value of the developed interfacial area ratio Sdr being 2.0 percent or more, high interface strength can be obtained. In the invention, a shape is specified with the developed interfacial area ratio of three-dimensional parameter considered most fitted to the evaluation. However, after processing with a similar high pass filter, it can be evaluated with RSm (an average length of roughness curve element) of two-dimensional parameter.

In the next place, a steel sheet suitably used as a base steel sheet of the invention will be explained.

A base steel sheet preferably contains, by mass percent, 0.25 percent or less of C, 0.03 to 2.0 percent of Si and 0.005 to 0.07 percent of P and has a composition satisfying the following equation (1).

Note
[C]+[P]≦[Si] (1)

Here, [C], [P] and [Si], respectively, mean contents (mass percent) of C, P and Si in the base steel sheet.

Reasons for components C, P and Si in the base steel sheet (mother material) being preferably in the above ranges are as follows. In what follows, contents (percent) of elements all mean mass percent.

C: 0.25 Percent or Less

Since the strength of steel can be easily increased when a content of C is increased, it is indispensable element for increasing the strength of the base steel sheet (mother material). However, since when the content of C is excessive, the ductility or the weldability of the base material is deteriorated, a content of C is preferably set at 0.25 percent or less. Furthermore, in the case of a steel sheet being used for the deep drawing, C desirably is not added as far as possible.

Si: 0.03 to 2.0 Percent

Si is a strengthening element of steel and an element that allows forming a continuous irregular portion at an interface between a coating layer and a base steel sheet. Though a detail is not understood, when a content of Si is less than 0.03 percent, a continuous irregular portion is formed with difficulty. On the other hand, since Si delays an alloying reaction, it is preferable not to add as far as possible from a viewpoint of alloying. Furthermore, when a content of Si exceeds 2.0 percent, an effect of improving the coating adhesion saturates, and a problem in that the alloying reaction is excessively delayed is likely to be caused. Accordingly, a content of Si is preferably in the range of 0.03 to 2.0 percent.

P: 0.005 to 0.07 Percent

P is a strengthening element of steel. However, it is a remarkable grain boundary segregation element, delays the reaction excessively and deteriorates the weldability. Accordingly, it is preferably reduced as far as possible; that is, P is contained preferably 0.07 percent or less. However, in order to reduce a content of P in the steel more than necessary, electrolytic iron high in the purity and grade is necessarily used, resulting in a problem in that economical efficiency is damaged. Accordingly, a content of P is preferably 0.005 percent or more.

In the invention, the contents of C, Si and P in the base steel sheet are limited in the above ranges and preferably satisfy the following equation (1).

Note
[C]+[P]≦[Si] (1)
Here, [C], [P] and [Si], respectively, mean contents (mass percent) of C, P and Si in the base steel sheet.

As mentioned above, when Si is added to steel, a continuous irregular portion is formed at an interface between the coating layer and the base steel sheet and thereby the coating adhesion can be greatly improved. However, when, in addition to Si, C and P are added in combination in the steel, a continuous irregular portion is suppressed from forming at an interface between the coating layer and the base steel sheet and thereby an improvement in the coating adhesion is disturbed. As mentioned above, C and P are strengthening elements of steel and indispensable elements for strengthening. That is, in order to form a continuous irregular portion that contributes to the coating adhesion, in accordance with amounts of C and P added, an amount of Si added is necessary to be controlled as shown in the above equation (1). In the case of [C]+[P]≦[Si], a continuous irregular portion can be easily formed at an interface between the coating layer and the base steel sheet.

Furthermore, elements other than C, Si and P may be contained in the steel.

As the other elements, Mn, S and Al can be cited as components that are contained in the base steel sheet. Preferable ranges of the elements are as follows.

Mn: 5 Percent or Less

Mn is a strengthening element of steel and can be contained as needs arise. However, when a content of Mn exceeds 5 percent, the workability and the economic efficiency of the base material are damaged; accordingly, a content Mn is preferably set at 5 percent or less. In order to obtain sufficient strengthening effect of the steel, Mn is preferably contained 0.5 percent or more.

S: 0.01 Percent or Less

S is an element inevitably present in steel. When S is contained more than 0.01 percent, the workability of the base steel sheet tends to deteriorate. Accordingly, a content of S is preferably set at 0.01 percent or less.

Al: 0.08 Percent or Less

Al works as a deoxidizing agent and can be added as needs arise. However, when a content of Al exceeds 0.08 percent, its effect only saturates and an increase in the manufacturing cost is invited; accordingly, a content of Al is preferably set at 0.08 percent or less. In order to develop a function as the deoxidizing agent, a content of Al is preferably set at 0.02 percent or more.

Furthermore, as the strengthening element of the steel, at least one kind selected from Ti, Nb and V can be contained. All of Ti, Nb and C can bind with C and N in the steel to form a fine precipitate and thereby strengthening the base steel sheet. When each of Ti, Nb and V components is added more than 0.2 percent, there is a tendency of damaging the workability; accordingly, contents of Ti, Nb and V each are preferably set at 0.2 percent or less.

Furthermore, at least one kind selected from Ti, Nb and V, when added in a proper amount, combines with dissolved P to form a fine precipitate, Fe—(Ti, Nb, V)—P, and thereby the dissolved P is partly rendered harmless. As a result, without excessively delaying a mutual diffusion reaction of Fe and Zn, the coating interface strength can be largely improved. In order to develop such an effect, in accordance with an amount of P in the steel, at least one kind of Ti, Nb and V satisfying the following equation (3) is preferably contained.
[Ti]+[Nb]+[V]≧[P] (3)
Here, [Ti], [Nb], [V] and [P], respectively, mean contents (mass percent) of Ti, Nb, V and P.

Components such as Cr, Mo, Cu, Ni, Ca, B, N and Sb other than the abovementioned components in the base steel sheet, since presence thereof does not at all contribute to the effects of the invention, may be added as needs arise. Reasons for addition and preferable ranges thereof are as follows.

Cr: 0.5 Percent or Less

This is a strengthening element of steel and can be added as needs arise. However, since the coating properties are deteriorated and the alloying nonuniformity is caused, it is preferably added by 0.5 percent or less.

Mo: 1.0 Percent or Less

This is a strengthening element of steel and can be added as needs arise. However, since the alloying delay is caused and the workability and the economic efficiency are damaged, it is preferably added by 1 percent or less.

Cu: 0.5 Percent or Less

This is a coating property improving element and can be added as needs arise. However, when it is added more than 0.5 percent, an effect thereof saturates and the economic efficiency is damaged. Accordingly, it is preferably added by 0.5 percent or less.

Ni: 0.5 Percent or Less

This is a coating property improving element and can be added as needs arise. However, when it is added more than 0.5 percent, an effect thereof saturates and the economic efficiency is damaged. Accordingly, it is preferably added by 0.5 percent or less.

Ca: 0.01 Percent or Less

This works as a deoxidizing agent and may be contained as needs arise. However, when it is added more than 0.01 percent, an effect thereof saturates. Accordingly, an addition of 0.01 percent or less is preferable.

B: 0.003 Percent or Less

Owing to grain boundary strengthening, the cold work embrittlement can be improved. However, since an effect thereof saturates at more than 0.003 percent, it is preferably added by 0.003 percent or less.

N: 0.01 Percent or Less

N comes in as an impurity. When it exceeds 0.01 percent, the ductility is deteriorated. Accordingly, it is preferably added by 0.01 percent or less.

Sb: 0.05 Percent or Less

This is a coating appearance improvement element and can be added as needs arise. However, when it is added more than 0.05 percent, an effect thereof saturates and the economic efficiency is damaged. Accordingly, it is preferably added by 0.05 percent or less.

The balance other than the abovementioned elements is preferably made of Fe and inevitable impurities.

Furthermore, in the invention, the tensile strength of the base steel sheet that is measured with a No. 5 test piece stipulated in JIS Z2201 and according to a tensile test method stipulated in JIS G3302 is preferably 440 MPa or more. When the base steel sheet is made a high tension steel sheet having the tensile strength of 440 MPa or more, in the fields of automobiles, home electric appliances, construction materials and so on, demands for higher strength and/or lighter weight base can be satisfied.

In the next place, a manufacturing method of forming an irregularity according to the invention (an irregularity that has a depth of 10 nm or more at a pitch of 0.5 μm or less and is present at least one per 5 μm of a length of the interface or an irregularity that has the developed interfacial area ratio Sdr of 2.0 percent or more when a surface shape of a base steel sheet observed by peeling a galvannealed layer is measured with a high pass filter with a cut-off wavelength of 0.5 μm) at an interface between a galvannealed layer and a base steel sheet will be explained below.

A galvannealed steel sheet according to the invention can be manufactured, with a steel sheet having, for instance, the abovementioned component composition as a base steel sheet, by applying a hot-dip galvanizing process and a subsequent galvannealing process. Here, the base steel sheet may be any one of a hot rolled steel sheet, a cold rolled steel sheet, or a steel sheet obtained by specially heat-treating these and is not restricted to particular one. The base steel sheet, after a surface thereof is cleansed by degreasing and/or by washing with acid in a pre-treatment process, or, by omitting the pre-treatment process, an oil component on a surface of the base steel sheet is burned and removed in a pre-heating furnace, is annealed at a temperature in the range of substantially 750 to 900 degree centigrade in a reducing atmosphere. Thereby, a scale on the surface of the base steel sheet is reduced and a surface state suitable for subsequent hot-dip galvanizing is obtained. Now, in the case of the base steel sheet in which Si is added to steel, even in a reducing atmosphere to Fe, in some cases, Si is selectively surface oxidized, resulting in forming an oxide concentrated on a surface. The silicon oxide oxidized selectively on a surface deteriorates the wettability with molten zinc during the coating to result in causing a bare spots surface. Accordingly, it is necessary to suppress the selective surface oxidation in a reducing atmosphere. Furthermore, as mentioned above, although Si in steel has a function of allowing forming a fine irregular portion at an interface between a coating layer and a base steel sheet, since silicon does not develop an effect when it exists as oxide, it is necessary to substantially suppress the selective surface oxidation in a reducing atmosphere from occurring.

Substantially suppressing the selective surface oxidation of Si from occurring means as mentioned above a state where the coating wettability is lowered and thereby the bare spots is inhibited from occurring; that is, there is no problems as far as it is a state where the bare spots is not caused.

As a method of obtaining a state where, with steel to which Si is added, Si does not substantially undergo the selective surface oxidation in a reducing atmosphere, though not particularly restricted, there is a method in which, prior to annealing in a reducing atmosphere, in a weak acidic atmosphere, for instance, in an inert gas atmosphere containing a slight amount such as 1 volume percent or less of oxygen, a pre-heating or heating process is applied. That is, in a weak acidic atmosphere a surface of the steel sheet is oxidized to form a thin iron scale followed by annealing in a reducing atmosphere to form reduced iron on the surface of the steel sheet, and thereby the selective surface oxidation of Si can be suppressed from occurring. The weak acidic atmosphere is an acidic atmosphere to an extent that allows sufficiently applying reduction in a later reducing atmosphere and not particularly restricted. As a weak acidic atmosphere, for instance, an atmosphere where 0.01 to 0.5 volume percent of oxygen is contained, a dew point is in the range of −20 to +20 degree centigrade, the balance is made of nitrogen and a temperature is in the range of 300 to 500 degree centigrade can be cited, and as a reducing atmosphere, for instance, an atmosphere where 3 to 20 volume percent of hydrogen is contained, the balance is made of nitrogen and a temperature is in the range of 750 to 900 degree centigrade can be cited.

When a surface of a steel sheet is oxidized in a weak acidic atmosphere to form a thin iron scale followed by annealing in a reducing atmosphere and thereby reduced iron is formed on a surface of the steel sheet, Fe oxide formed in the weak acidic atmosphere is reduced in an annealing process in the subsequent reducing atmosphere and silicon oxide, without being oxidized even in the annealing process in the reducing atmosphere, remains as internal oxide in base steel immediate below a surface of the base steel sheet. The internal oxide is distinguished from an oxide that is formed according to the selective surface oxidization of Si and works so as to suppress Si from being selectively surface oxidized during the annealing in a reducing atmosphere. The internal oxide remains in a hot-dip galvanizing process and in a subsequent galvannealing process.

When the pre-heating or heating process in a weak acidic atmosphere cannot be applied from an apparatus point of view, after a primary heating is applied at a relatively high temperature in the range of 800 to 900 degree centigrade in a reducing atmosphere, a surface oxide is removed by applying pickling or polishing. Subsequently, after a secondary heating is carried out at a relatively low temperature of 800 degree centigrade or less in a reducing atmosphere, the coating is applied without exposing to air, and thereby Si can be substantially suppressed from being selectively surface oxidized. A method of obtaining a state where, as mentioned above, Si is not substantially selectively surface oxidized in a reducing atmosphere is not restricted to particular one and in any method an effect of the invention is not disturbed.

The base steel sheet after the annealing is cooled in the reducing atmosphere to a temperature suitable for the coating, preferably in the range of 440 to 540 degree centigrade, dipped without exposing to air in a molten zinc coating bath to apply the coating. At this time, an atmosphere immediately before the coating is made an atmosphere having an oxygen concentration of 0.005 volume percent or less. This is because oxygen, in particular, lowers the reactivity of a surface of the base steel sheet to disturb the formation of a fine irregularity at an interface between a coating layer and the base steel sheet. Residual gases other than oxygen, not particularly affecting on the formation of the fine irregularity, are not limited. For instance, an atmosphere containing 3 to 20 volume percent of hydrogen and the balance of nitrogen can be cited. Furthermore, since oxygen lowers the wettability with molten zinc to induce the bare spots, also from this meaning, it is better to be low.

The hot-dip galvanizing process has only to be conducted according to an existing method. For instance, it is preferable that a temperature of a coating bath is set in the range of substantially 450 to 500 degree centigrade and a concentration of Al in the coating bath is set in the range of 0.10 to 0.15 mass percent. However, depending on components in the steel, the coating conditions mentioned above have to be altered. However, difference of the coating conditions, not bringing about any contribution to the effects of the invention, is not particularly restricted.

As a method of adjusting a thickness of a coating layer after the coating, without being restricted to a particular one, a general gas-wiping is used; that is, a gas pressure of the gas-wiping, a distance between a wiping nozzle and a steel sheet and so on are used to adjust. At this time, a thickness of the coating layer is preferably in the range of 3 to 15 μm. When it is less than 3 μm, the rust resistance cannot be sufficiently obtained. On the other hand, when it exceeds 15 μm, not only an improving effect of the rust resistance saturates but also the workability and the economic efficiency unfavorably tend to be lowered.

A method of galvannealing process after the coating thickness is adjusted can be applied by use of a method such as gas heating or induction heating. However, it is necessary that an average temperature rise speed during heating to a galvannealing temperature is 20 degree centigrade/s or more. This is because in the case of less than 20 degree centigrade/s, a staying time in a low temperature region is long to cause a delay in galvannealing reaction, and thereby a fine irregularity at an interface between a coating layer and a base steel sheet is inhibited from forming.

Furthermore, in the case of Ti, Nb and V being contained in the above range in a base steel sheet, a temperature rise speed during heating in the galvannealing process and a content of Si in the base steel sheet are necessary to satisfy the equation (2) below.
ST≧3.25/[Si] (2)

Here, in the equation, ST expresses a temperature rise speed (degree centigrade/s) and [Si] denotes a content (mass percent) of Si in the steel sheet.

According to inventors' research, it was found that when Ti, Nb and V are contained in steel, in the case of a content of Si being low, even when a temperature rise speed in the galvannealing process is set at 20 degree centigrade/s or more, in some cases, an inventive fine irregularity in an interface between the coating layer and the base steel sheet is not formed; that is, a temperature rise speed is necessary to raise in accordance with the content of Si.

FIG. 6 is a graph showing, of steel sheets that contain at least one kind of Ti, Nb and V in a range that satisfies the equation (3), influence of a content of Si and a temperature rise speed on a an area ratio of fine irregularity. It is found that when the equation (2) is satisfied, the area ratio of the fine irregularity becomes 10 percent or more.

Although a time of galvannealing is not particularly restricted, a content of Fe in the coating layer is preferably controlled in the range of 8 to 13 mass percent. When the content of Fe in the coating layer is less than 8 mass percent, since the aforementioned Fe—Zn alloy phase is not sufficiently formed and a soft η-Zn phase remains on a surface of the coating layer, in some cases, the workability and the adhesion are damaged. On the other hand, when the content of Fe in the coating layer exceeds 13 mass percent, there is a problem in that a hard and brittle Fe—Zn alloy phase (for instance, a Γ phase or a Γ1 phase) is formed excessively thick in an interface between the coating layer and the base steel sheet, and thereby the embrittlement in the interface between the coating layer and the steel sheet is forwarded.

“A content of Fe in a coating layer” here denotes a mass percentage of Fe in a coating layer to an entire coating layer, that is, an average content of Fe. A method of measuring a content of Fe in the coating layer is carried out in such manner that for instance, a galvannealed layer is dissolved with hydrochloric acid added with an inhibitor followed by measuring by ICP (Inductively Coupled Plasma) emission spectrometry.

A method of controlling a content of Fe in the coating layer in the range of 8 to 13 mass percent is not restricted to particular one. In general, it is controlled through a sheet temperature and a staying time in a galvannealing heating furnace and so on. The staying time in the furnace is preferably shorter from a viewpoint of the productivity and specifically operated within substantially 5 to 30 sec. Furthermore, the sheet temperature, though being selected depending on the staying time in the furnace, is generally operated in the range of 460 to 600 degree centigrade. In the case of less than 460 degree centigrade, in order to control the content of Fe in the coating layer in the range of 8 to 13 mass percent, a long galvannealing process is forced to operate; accordingly, it becomes necessary to make a speed of steel sheet extremely slow or to use a very long galvannealing furnace. As a result, since there is a problem in that the productivity is lowered or huge equipment expense is necessary, it is preferably operated at 460 degree centigrade or more. On the other hand, when it exceeds 600 degree centigrade, there is a problem in that in an interface between the coating layer and the base steel sheet, a hard and brittle Fe—Zn alloy phase (for instance, a Γ phase or a Γ1 phase) tends to be formed excessively thick, and thereby the embrittlement of the interface between the coating layer and the base steel sheet is enhanced. Accordingly, it is preferably operated at 600 degree centigrade or less.

After the galvannealing process, cooling is immediately followed. A method of cooling, though not particularly restricted, is desirably applied by quenching at 30 degree centigrade/s or more to 420 degree centigrade where the galvannealing reaction comes to completion, for instance, an existing method such as gas cooling and mist cooling has only to be applied.

In what was mentioned above, only one example of embodiments of the invention is shown and the invention can be variously modified in the range of claims.

### EXAMPLE 1

Each of steel ingots having a chemical composition shown in Table 1 was heated to 1250 degree centigrade to apply hot rolling followed by removing a scale on a surface, and thereby a hot rolled steel sheet having a thickness of 2.0 mm was prepared. Subsequently, cold rolling at the reduction rate of 50 percent was applied to form a cold rolled steel sheet having a thickness of 1.0 mm, followed by cutting out into a width of 70 mm and a length of 180 mm. This was subjected to primary heating at 830 degree centigrade in a heating furnace in a nitrogen atmosphere that contains 3 volume percent of hydrogen and has a dew point of −30 degree centigrade to cleanse a surface thereof, and thereby a base steel sheet was prepared. After the base steel sheet was dipped in 5 percent hydrochloric acid at 60 degree centigrade for 10 sec to apply pickling, recrystallization annealing and hot-dip galvanizing (hereinafter, simply referred to as “galvanizing”) were applied by use of a laboratory galvanizing simulator. Conditions for the recrystallization annealing and the galvanizing were as follows.

TABLE 1

| | The balance of steel | | | | | | |
|---|---|---|---|---|---|---|---|
| | composition (mass %) is Fe | | | | | | |
| Steel | and inevitable impurities | | | | | | |
| No. | C | Si | Mn | P | sol.Al | S | Note |
| 1A | 0.03 | 0.1 | 2.2 | 0.065 | 0.03 | 0.003 | Example |
| 1B | 0.08 | 0.1 | 0.5 | 0.01 | 0.029 | 0.003 | |
| 1C | 0.08 | 0.25 | 2 | 0.01 | 0.042 | 0.003 | |
| 1D | 0.08 | 0.2 | 2.6 | 0.015 | 0.035 | 0.003 | |
| 1E | 0.03 | 0.6 | 2 | 0.01 | 0.05 | 0.003 | |
| 1F | 0.08 | 0.2 | 2 | 0.01 | 0.041 | 0.003 | |
| 1G | 0.08 | 0.6 | 1.95 | 0.01 | 0.045 | 0.003 | |
| 1H | 0.15 | 0.8 | 2.6 | 0.012 | 0.065 | 0.003 | |
| 1I | 0.1 | 0.25 | 2 | 0.015 | 0.029 | 0.003 | |
| 1J | 0.03 | 0.25 | 1.6 | 0.03 | 0.033 | 0.003 | |
| 1K | 0.16 | 0.2 | 0.8 | 0.01 | 0.041 | 0.003 | |
| 1L | 0.25 | 0.3 | 0.8 | 0.012 | 0.041 | 0.003 | |
| 1M | 0.03 | 0.5 | 1.5 | 0.02 | 0.036 | 0.003 | |
| 1N | 0.003 | 0.02 | 0.28 | 0.02 | 0.031 | 0.003 | Comparative |
| 1O | 0.002 | 0.02 | 0.09 | 0.014 | 0.04 | 0.003 | Example |
| 1P | 0.15 | 0.05 | 1.2 | 0.012 | 0.039 | 0.003 | |
| 1Q | 0.15 | 0.1 | 1.2 | 0.012 | 1.5 | 0.003 | |
| 1R | 0.05 | 0.02 | 0.8 | 0.008 | 0.055 | 0.003 | |
| 1S | 0.018 | 0.02 | 0.18 | 0.01 | 0.033 | 0.003 | |
| 1T | 0.01 | 0.1 | 1 | 0.075 | 0.035 | 0.003 | |
| 1U | 0.004 | 0.02 | 0.14 | 0.021 | 0.045 | 0.003 | |
| 1V | 0.08 | 0.07 | 2 | 0.01 | 0.06 | 0.003 | |
| 1W | 0.002 | 0.02 | 0.3 | 0.035 | 0.033 | 0.003 | |
| 1X | 0.12 | 0.1 | 3 | 0.015 | 1.5 | 0.003 | |
| 1Y | 0.08 | 0.05 | 1.5 | 0.03 | 0.041 | 0.003 | |

<Recrystallization Annealing>
Atmosphere: 5 volume percent hydrogen+nitrogen (dew point: −35 degree centigrade)
Temperature: 750 degree centigrade
Holding time: 20 sec
   <Coating condition>
Bath composition: Zn+0.14 mass percent Al (Fe saturation)
Bath temperature: 460 degree centigrade
Sheet temperature at the time of coating: 460 degree centigrade
Coating time: 1 sec
Concentration of oxygen in an atmosphere immediately before the coating: conditions described in Table 2 (the balance 5 volume percent hydrogen+nitrogen (dew point: −35 degree centigrade))

Obtained coating steel sheets contained 0.2 to 0.5 mass percent of Al and 0.5 to 2 mass percent of Fe in the coating layers. After the coating process above, a galvannealing process was applied in air in an electric heater. Temperature rise speeds and galvannealing temperatures in the galvannealing process were the conditions described in Table 2.

Of each of obtained coating steel sheets, a cooling atmosphere from the recrystallization annealing to the coating, a thickness of a coating layer, a temperature rise speed, a temperature and a holding time in the galvannealing process, a content of Fe in the coating layer, a ratio of fine irregularity formed in an interface between the coating layer and a base steel sheet and a developed interfacial area ratio Sdr are shown in Table 2. Furthermore, a method of evaluating the coating adhesion 1 of the obtained coating steel sheet is shown below and evaluation results are shown together in Table 2.

<Ratio of Interfacial Irregularity>

A cross section of an interface of the coating layer and the steel sheet in the obtained steel sheet was observed with a SEM (TEM was used together) over a length of 10 μm in five viewing fields in an arbitrary cross section and a ratio at which fine irregularity (having a depth of 10 nm or more at a pitch of 0.5 μm or less) occupies in an entire coating cross section is taken as an interfacial irregularity ratio (%).

<Developed Interfacial Area Ratio Sdr>

The coating layer was removed by subjecting to constant-potential electrolysis in an alkaline solution containing NaOH, NaCl, and triethanolamine and thereby an interface between the coating layer and the base steel sheet was exposed. The exposed surface was measured of a surface shape by use of an electron beam three-dimensional surface roughness analyzer ERA-8800FE (manufactured by Elionics Co., Ltd.). A test sample, in order to avoid an influence of a composition of surface, was coated with Au with a thickness of several tens nanometers and supplied for measurement. The shape analysis measurement was performed at an acceleration voltage of 15 kV, a viewing field magnified by 10000 times (viewing field area is 12 μm×9 μm) was collected at the resolving power of 1200×900 points, followed by data processing. A value of the developed interfacial area ratio Sdr was obtained by averaging results obtained by measuring arbitrarily selected three areas. In the calibration that was performed in a height direction with the device, a SHS thin film step standard (with three steps of 18, 88 and 450 nm) for contact stylus and optical surface roughness analyzer manufactured by VLSI Standard Inc. having traceable performance to the NIST that is National Institute of Standard and Technology in the U.S. was used. Furthermore, a high pass filter having a cut-off wavelength of 0.5 μm was applied to supply for calculation of three-dimensional shape parameter.

<Thickness of Coating Layer>

A cross section of the obtained coating steel sheet was observed with an optical microscope (magnification: 400 times) a thickness of the coating layer was measured at arbitrary three points, followed by averaging these, and an averaged value was taken as a thickness of the coating layer (μm).

<Content of Fe in the Coating Layer>

The coating layer of the obtained coating steel sheet was dissolved with hydrochloric acid added with an inhibitor and Zn and Fe in the coating layer were quantitatively analyzed by ICP emission spectrometry. A mass percentage (mass percent) of Fe to (Zn+Fe) was taken as a content of Fe in the coating layer.

(Evaluation of the coating adhesion 1)

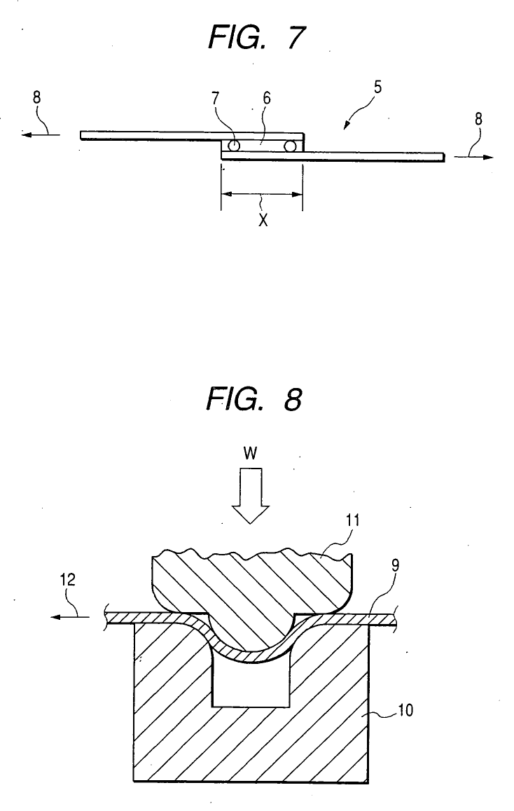

From the obtained coating steel sheet, two test pieces having a width of 25 mm and a length of 80 mm were cut out, after dipping in a rust preventive oil: 550 KH (manufactured by Nihon Parkerizing Co., Ltd.), were left in air standing obliquely for 24 hr, and thus obtained ones were supplied as test samples. As shown in FIG. 7, after an adhesive 6 was coated on surface portions that are adhered of test samples 5, the test samples were stacked so that a length of an overlapped portion X may be 20 mm. As the adhesive 6, E-56 (manufactured by Sunrise MSI Co.,) was used, and by use of spacers 7 (SUS304 wire having a diameter of 0.15 mm) a thickness of the adhesive was maintained constant for each of the test pieces. After the adhesive was coated, heat treatment was applied at 170 degree centigrade for 20 min in a drying oven, thereafter tensile test applying tension in directions of arrow marks 8 was applied by use of an autograph (manufactured by Shimadzu Corporation), and thereby the tensile shear strength and peeling mode were measured, followed by evaluating according to criteria below. The tensile shear strength was evaluated with a ratio (%) to the strength obtained when with a cold rolled steel sheet (non-coating material) having the same steel composition and the same size the tensile test was applied.

<Evaluation Criteria of Tensile Shear Strength>

◯◯: very good (strength ratio: exceeding 90%)
◯: good (strength ratio: exceeding 80% and 90% or less)
Δ: fair (strength ratio: exceeding 60% and 80% or less) and
x: bad (strength ratio: 60% or less)
   <Evaluation Criteria of Peeling Mode>
◯◯: very good (coagulation peeling in the adhesive)
Δ: fair (partially peeling at an interface of coating layer/base steel sheet)
x: bad (overall peeling at an interface of coating layer/base steel sheet)

In the evaluation criteria of the peeling mode, the peeling at an interface of coating layer/base steel sheet means the peeling at an interface of the coating layer and the base steel sheet. However, depending on the peeling mode, in some cases, the peeling at an interface of the coating layer and the base steel sheet does not occur uniformly, accordingly cases where the peeling occurs within 2 μm on a side of the coating layer or on a side of the base steel sheet from the interface of the coating layer and the base steel sheet are included.

TABLE 2

| | | | | | | Galvannealed steel sheet | | | | | | |
|---|---|---|---|---|---|---|---|---|---|---|---|---|
| | | Concentration of | Galvannealing | | | | | Base steel | | Evaluation | | |
| | | oxygen in a cooling | condition | | | | | sheet | | result | | |
| | | atmosphere until | Temper- | | | | | Developed | Ratio of fine | Coating | | |
| Test | | the coating after | ature | | | Coating layer | | interfacial | irregularity | adhesion 1 | | |
| sam- | | the recrystallization | rise | Galvannealing | Holding | Thick- | Content of | area | in an | Tensile | | |
| ple | Steel | annealing | speed | temperature | time | ness | Fe | ratio Sdr | interface | shear | Peeling | |
| No. | No. | (vol. %) | (° C./s) | (° C.) | (s) | (μm) | (mass %) | (%) | (%) | strength | mode | Note |
| 1 | 1A | 0.002 | 25 | 490 | 15 | 7 | 10.8 | 2.2 | 15 | ◯ | ◯◯ | Exam- |
| 2 | 1B | 0.002 | 20 | 480 | 10 | 6 | 9.2 | 2.1 | 15 | ◯◯ | ◯◯ | ple |
| 3 | 1C | 0.001 | 25 | 490 | 9 | 3 | 10.3 | 2.5 | 50 | ◯◯ | ◯◯ | |
| 4 | 1C | 0.002 | 25 | 490 | 15 | 7 | 9.9 | 2.5 | 45 | ◯◯ | ◯◯ | |
| 5 | 1C | 0.002 | 25 | 490 | 22 | 6 | 12.5 | 2.8 | 75 | ◯◯ | ◯◯ | |
| 6 | 1C | 0.003 | 30 | 510 | 20 | 14 | 11.2 | 2.6 | 60 | ◯◯ | ◯◯ | |
| 7 | 1D | 0.002 | 25 | 500 | 16 | 9 | 11.8 | 2.6 | 55 | ◯◯ | ◯◯ | |
| 8 | 1E | 0.002 | 35 | 520 | 20 | 8 | 10.6 | 2.6 | 65 | ◯◯ | ◯◯ | |
| 9 | 1F | 0.002 | 25 | 490 | 15 | 10 | 11.0 | 2.3 | 30 | ◯◯ | ◯◯ | |
| 10 | 1G | 0.002 | 30 | 520 | 15 | 6 | 11.3 | 2.5 | 50 | ◯◯ | ◯◯ | |
| 11 | 1H | 0.004 | 30 | 520 | 20 | 6 | 10.6 | 2.3 | 25 | ◯◯ | ◯◯ | |
| 12 | 1I | 0.002 | 20 | 460 | 12 | 4 | 9.1 | 2.1 | 10 | ◯ | ◯◯ | |
| 13 | 1J | 0.002 | 25 | 490 | 20 | 7 | 10.6 | 2.8 | 70 | ◯◯ | ◯◯ | |
| 14 | 1K | 0.002 | 30 | 510 | 15 | 6 | 11.2 | 2.8 | 75 | ◯◯ | ◯◯ | Exam- |
| 15 | 1L | 0.004 | 25 | 480 | 18 | 8 | 11.0 | 2.8 | 65 | ◯◯ | ◯◯ | ple |
| 16 | 1M | 0.002 | 35 | 540 | 6 | 5 | 9.2 | 2.8 | 70 | ◯◯ | ◯◯ | |
| 17 | 1N | 0.003 | 20 | 520 | 8 | 7 | 10.0 | 1.6 | 0 | X | Δ | Com- |
| 18 | 1O | 0.002 | 30 | 470 | 15 | 10 | 9.5 | 1.5 | 0 | X | X | para- |
| 19 | 1P | 0.002 | 20 | 500 | 20 | 6 | 12.3 | 1.7 | 0 | Δ | X | tive |
| 20 | 1Q | 0.002 | 20 | 490 | 15 | 6 | 10.0 | 1.9 | 0 | Δ | Δ | Exam- |
| 21 | 1R | 0.002 | 35 | 490 | 7 | 7 | 8.2 | 1.8 | 0 | Δ | Δ | ple |
| 22 | 1S | 0.003 | 20 | 520 | 15 | 8 | 12.8 | 1.4 | 0 | X | X | |
| 23 | 1T | 0.002 | 20 | 520 | 22 | 9 | 11.5 | 1.7 | 0 | X | Δ | |
| 24 | 1U | 0.002 | 20 | 510 | 12 | 10 | 11.5 | 1.6 | 0 | X | X | |
| 25 | 1V | 0.001 | 20 | 500 | 9 | 8 | 9.9 | 1.8 | 0 | X | Δ | |
| 26 | 1W | 0.002 | 30 | 490 | 12 | 10 | 9.6 | 1.9 | 0 | Δ | Δ | |
| 27 | 1X | 0.002 | 20 | 520 | 15 | 11 | 11.6 | 1.7 | 0 | X | X | |
| 28 | 1Y | 0.002 | 20 | 470 | 18 | 9 | 11.1 | 1.7 | 0 | Δ | Δ | |
| 29 | 1B | 0.007 | 20 | 480 | 10 | 6 | 9.2 | 1.9 | 5 | Δ | Δ | |

From the evaluation results shown in Table 2, it is found that galvannealed steel sheets according to the invention (examples), in comparison with existing steel sheets (comparative examples), are largely heightened in the strength of the interface between the coating layer and the base steel sheet and improved in the coating adhesion thereof.

### EXAMPLE 2

Each of steel ingots having a chemical composition shown in Table 3 was heated at 1250 degree centigrade to apply the hot rolling followed by removing a scale on a surface, and thereby a hot rolled steel sheet having a thickness of 2.0 mm was prepared. Subsequently, the cold rolling at the reduction rate of 50 percent was applied to form a cold rolled steel sheet having a thickness of 1.0 mm, followed by cutting out into a width of 70 mm and a length of 180 mm, further followed by surface cleaning, and thereby a base steel sheet was obtained. The base steel sheet was dipped in 5 percent hydrochloric acid at 60 degree centigrade for 10 sec to apply pickling, thereafter, subjected to primary heating by holding at 400 degree centigrade for 1 sec in a nitrogen atmosphere (dew point: +20 degree centigrade) containing 0.1 volume percent of oxygen, and thereafter subjected to a secondary heating by holding at 750 degree centigrade for 1 sec in a nitrogen atmosphere (dew point: +20 degree centigrade) containing 5 volume percent of hydrogen. To the heat treated base steel sheet, recrystallization annealing and coating were applied by use of a laboratory galvanizing simulator. Conditions for the recrystallization annealing and the coating were as follows.

TABLE 3

| | The balance of steel composition (mass %) | | | | | | | | |
|---|---|---|---|---|---|---|---|---|---|
| | is Fe and inevitable impurities | | | | | | | | |
| Steel No. | C | Si | Mn | P | Ti | Nb | V | 3.25/Si | Note |
| 2A | 0.025 | 0.13 | 2 | 0.03 | 0.02 | 0.01 | 0.01 | 25 | Example |
| 2B | 0.08 | 0.1 | 0.5 | 0.01 | 0.02 | 0.01 | — | 33 | |
| 2C | 0.08 | 0.25 | 2 | 0.01 | 0.02 | 0.06 | — | 13 | |
| 2D | 0.08 | 0.2 | 2.6 | 0.015 | 0.02 | 0.05 | — | 16 | |
| 2E | 0.075 | 0.6 | 2 | 0.01 | — | 0.03 | — | 5 | |
| 2F | 0.08 | 0.2 | 2 | 0.01 | 0.02 | — | — | 16 | |
| 2G | 0.08 | 0.6 | 1.95 | 0.01 | 0.01 | 0.01 | — | 5 | |
| 2H | 0.15 | 0.8 | 2.6 | 0.012 | 0.01 | 0.01 | — | 4 | |
| 2I | 0.1 | 0.3 | 2 | 0.015 | — | 0.02 | 0.02 | 11 | |
| 2J | 0.08 | 0.25 | 1.6 | 0.03 | — | 0.025 | 0.05 | 13 | |
| 2K | 0.16 | 0.2 | 0.8 | 0.01 | 0.01 | 0.01 | — | 16 | |
| 2L | 0.25 | 0.3 | 0.8 | 0.012 | 0.02 | 0.03 | — | 11 | |
| 2M | 0.04 | 0.16 | 3 | 0.04 | 0.02 | 0.03 | 0.01 | 20 | |
| 2N | 0.003 | 0.02 | 0.28 | 0.02 | 0.02 | 0.01 | — | 163 | Comparative |
| 2O | 0.002 | 0.02 | 0.09 | 0.014 | 0.02 | 0.01 | — | 163 | Example |
| 2P | 0.15 | 0.1 | 1.2 | 0.012 | 0.01 | — | — | 33 | |
| 2Q | 0.15 | 0.02 | 1.2 | 0.012 | 0.02 | 0.01 | 0.01 | 163 | |
| 2R | 0.05 | 0.02 | 0.8 | 0.008 | 0.02 | 0.05 | — | 163 | |
| 2S | 0.018 | 0.02 | 0.18 | 0.01 | 0.02 | 0.01 | — | 163 | |
| 2T | 0.01 | 0.12 | 1 | 0.075 | 0.02 | 0.05 | — | 27 | |
| 2U | 0.004 | 0.03 | 0.14 | 0.04 | 0.01 | 0.01 | — | 108 | |
| 2V | 0.08 | 0.07 | 2 | 0.01 | 0.02 | 0.01 | — | 46 | |
| 2W | 0.002 | 0.02 | 0.1 | 0.01 | 0.01 | 0.01 | — | 163 | |
| 2X | 0.002 | 0.03 | 0.3 | 0.035 | 0.02 | 0.01 | 0.02 | 108 | |
| 2Y | 0.12 | 0.02 | 1.5 | 0.015 | 0.02 | 0.01 | — | 163 | |
| 2Z | 0.08 | 0.05 | 1.5 | 0.03 | 0.02 | 0.03 | — | 65 | |

<Recrystallization annealing>
Atmosphere: 5 volume percent hydrogen+nitrogen (dew point: −35 degree centigrade)
Temperature: 830 degree centigrade
Holding time: 20 sec
   <Coating Condition>
Bath composition: Zn+0.13 mass percent Al (Fe saturation)
Bath temperature: 460 degree centigrade
Sheet temperature at the time of coating: 460 degree centigrade
Coating time: 1 sec
Concentration of oxygen in an atmosphere immediately before the coating: conditions described in Table 4 (the balance 5 volume percent hydrogen+nitrogen (dew point: −35 degree centigrade))

Obtained coating steel sheets contained 0.2 to 0.5 mass percent of Al and 0.5 to 2 mass percent of Fe in the coating layer. After the coating process, the galvannealing process was applied in air in an electric heater. The temperature rise speeds and galvannealing temperatures in the galvannealing process were the conditions described in Table 4.

Of each of obtained coating steel sheets, a cooling atmosphere from the recrystallization annealing to the coating, a thickness of a coating layer, a temperature rise speed, a temperature and a holding time in the galvannealing process, a content of Fe in the coating layer, a ratio of fine irregularity formed in an interface between the coating layer and a base steel sheet and a developed interfacial area ratio Sdr were investigated similarly to a method explained in the example 1. Furthermore, in addition to the evaluation of the abovementioned coating adhesion 1, evaluation of the coating adhesion 2 shown below was carried out. Results of these are shown in Table 4. Furthermore, a method of evaluating the coating adhesion of the obtained coating steel sheet is shown below and evaluation results are shown together in Table 4.

(Evaluation of the Coating Adhesion 2)

From each of the obtained steel sheets, a test piece having a width of 20 mm and a length of 180 mm was cutout followed by removing burrs, after dipping in rust-preventive oil 550 KH (manufactured by Nihon Parkerizing Co., Ltd.), left in air for 24 hr while standing obliquely, and thus obtained one was used as a test sample. A test sample 9 was disposed on a recessed die 10 such as shown in FIG. 8, and a test in which a bending and unbending operation is applied by lowering a projected die 11 and thereby indenting a surface of the test sample 9 with a load W was carried out. A surface of the die was polished with #1200 polishing paper and cleaning of accretions was carried out each time. An indentation load P of the die was set at 8 kN and the drawing speed of the test sample was set at 20 mm/s. After the test, the test sample was slightly degreased, followed by adhering a cellophane tape (width: 24 mm, manufactured by Nichiban Corp.) to a sliding portion with the die. An amount of Zn adhered to the cellophane tape when it was peeled was measured as the number of counts by X-ray fluorescence analysis, and evaluation was carried out according to the following criteria.

<Evaluation Criteria of the Coating Adhesion 2>

◯◯: Very good (number of counts: 25 or less)
◯: good (number of counts: more than 25 and 50 or less)
Δ: fair (number of counts: more than 50 and 150 or less)

x: bad (number of counts: more than 150)

TABLE 4

| | | Concentration of | | | | | | | | | | | |
|---|---|---|---|---|---|---|---|---|---|---|---|---|---|
| | | oxygen in a | | | | Galvannealed steel sheet | | | | | | | |
| | | cooling | | | | | | Base steel | | | | | |
| | | atmosphere | Alloying condition | | | | | sheet | Ratio of | Evaluation result | | | |
| | | until the | Temper- | | | Coating layer | | Developed | fine | Coating | | | |
| Test | | coating after the | ature | Alloying | | | Content | interfacial | irregularity | adhesion 1 | | Coating | |
| sam- | | recrystallization | rise | temper- | Holding | Thick- | of Fe | area | in an | Tensile | | adhe- | |
| ple | Steel | annealing | speed | ature | time | ness | (mass | ratio Sdr | interface | shear | Peeling | sion | |
| No. | No. | (vol. %) | (° C./s) | (° C.) | (s) | (μm) | %) | (%) | (%) | strength | mode | 2 | Note |
| 1 | 2A | 0.001 | 30 | 520 | 15 | 6 | 10.5 | 2.6 | 60 | ◯ | ◯◯ | ◯◯ | Exam- |
| 2 | 2B | 0.002 | 35 | 480 | 12 | 7 | 9.5 | 2.6 | 50 | ◯◯ | ◯◯ | ◯◯ | ple |
| 3 | 2C | 0.001 | 25 | 490 | 10 | 3 | 10.5 | 2.6 | 55 | ◯◯ | ◯◯ | ◯◯ | |
| 4 | 2C | 0.001 | 25 | 490 | 15 | 7 | 9.9 | 2.5 | 50 | ◯◯ | ◯◯ | ◯◯ | |
| 5 | 2C | 0.002 | 25 | 490 | 25 | 6 | 12.8 | 2.8 | 70 | ◯◯ | ◯◯ | ◯ | |
| 6 | 2C | 0.002 | 25 | 520 | 25 | 14 | 11.0 | 2.7 | 65 | ◯◯ | ◯◯ | ◯◯ | |
| 7 | 2D | 0.002 | 25 | 500 | 15 | 9 | 11.6 | 2.6 | 50 | ◯◯ | ◯◯ | ◯◯ | |
| 8 | 2E | 0.003 | 25 | 520 | 17 | 8 | 10.4 | 2.5 | 50 | ◯◯ | ◯◯ | ◯◯ | |
| 9 | 2F | 0.002 | 25 | 490 | 15 | 11 | 11.2 | 2.6 | 60 | ◯◯ | ◯◯ | ◯◯ | |
| 10 | 2G | 0.002 | 25 | 500 | 20 | 6 | 10.9 | 2.6 | 50 | ◯◯ | ◯◯ | ◯◯ | |
| 11 | 2H | 0.004 | 25 | 520 | 15 | 6 | 9.9 | 2.5 | 45 | ◯◯ | ◯◯ | ◯◯ | |
| 12 | 2I | 0.002 | 25 | 460 | 8 | 4 | 8.9 | 2.1 | 15 | ◯ | ◯◯ | ◯◯ | |
| 13 | 2J | 0.001 | 25 | 490 | 20 | 7 | 10.6 | 2.5 | 50 | ◯◯ | ◯◯ | ◯◯ | |
| 14 | 2K | 0.002 | 25 | 460 | 30 | 7 | 11.2 | 2.6 | 60 | ◯◯ | ◯◯ | ◯◯ | |
| 15 | 2L | 0.002 | 25 | 480 | 20 | 8 | 11.1 | 2.5 | 55 | ◯◯ | ◯◯ | ◯◯ | Exam- |
| 16 | 2M | 0.002 | 25 | 560 | 5 | 6 | 9.2 | 2.1 | 25 | ◯◯ | ◯◯ | ◯◯ | ple |
| 17 | 2N | 0.002 | 10 | 520 | 8 | 9 | 10.0 | 1.9 | 8 | Δ | Δ | ◯◯ | Com- |
| 18 | 2O | 0.002 | 35 | 530 | 5 | 5 | 9.6 | 1.6 | 0 | Δ | Δ | ◯◯ | para- |
| 19 | 2P | 0.002 | 15 | 490 | 12 | 6 | 10.0 | 1.9 | 7 | Δ | X | ◯◯ | tive |
| 20 | 2Q | 0.003 | 25 | 490 | 8 | 6 | 9.0 | 1.5 | 0 | Δ | Δ | ◯◯ | Exam- |
| 21 | 2R | 0.002 | 25 | 490 | 7 | 7 | 8.2 | 1.6 | 0 | Δ | Δ | ◯ | ple |
| 22 | 2S | 0.002 | 25 | 500 | 15 | 6 | 12.4 | 1.7 | 3 | X | X | X | |
| 23 | 2T | 0.002 | 25 | 480 | 18 | 7 | 11.2 | 1.8 | 8 | X | Δ | ◯ | |
| 24 | 2U | 0.002 | 25 | 510 | 8 | 9 | 10.4 | 1.6 | 0 | X | X | Δ | |
| 25 | 2V | 0.002 | 25 | 500 | 9 | 8 | 9.9 | 1.7 | 6 | Δ | Δ | ◯◯ | |
| 26 | 2W | 0.002 | 25 | 490 | 15 | 7 | 10.3 | 1.9 | 9 | Δ | ◯ | Δ | |
| 27 | 2X | 0.002 | 25 | 520 | 7 | 10 | 9.5 | 1.8 | 5 | Δ | Δ | ◯◯ | |
| 28 | 2Y | 0.002 | 25 | 480 | 15 | 8 | 10.5 | 1.4 | 0 | X | X | Δ | |
| 29 | 2Z | 0.002 | 25 | 470 | 18 | 9 | 11.1 | 1.6 | 2 | Δ | Δ | X | |
| 30 | 2B | 0.010 | 35 | 480 | 12 | 7 | 9.5 | 1.9 | 5 | Δ | Δ | Δ | |

From the evaluation results shown in Table 4, it is found that galvannealed steel sheets according to the invention (examples), in comparison with existing steel sheets (comparative examples), are largely heightened in the interfacial strength between the coating layer and the base steel sheet and improved in the coating adhesion.

### EXAMPLE 3

Each of steel ingots having a chemical composition shown in Table 5 was heated at 1250 degree centigrade to apply hot rolling followed by removing a black skin on a surface, and thereby a hot rolled steel sheet having a thickness of 2.0 mm was prepared. Subsequently, cold rolling at the reduction rate of 65 percent was applied to form a cold rolled steel sheet having a thickness of 0.7 mm, followed by cutting out into a width of 70 mm and a length of 180 mm, further followed by applying a primary heating at 830 degree centigrade in a heating furnace in a nitrogen atmosphere that has a dew point of −30 degree centigrade and contains 3 volume percent of hydrogen to apply surface cleaning, and thereby a base steel sheet was obtained. The base steel sheet was dipped in 5 percent hydrochloric acid at 60 degree centigrade for 10 sec to apply pickling. Thereafter, recrystallization annealing and coating were applied by use of a laboratory galvanizing simulator. Conditions for the recrystallization annealing and the coating are as follows.

TABLE 5

| | The balance of steel | | | | | |
|---|---|---|---|---|---|---|
| | composition (mass %) is Fe | | | | | |
| Steel | and inevitable impurities | | | | | |
| No. | C | Si | Mn | P | Others | Note |
| 3A | 0.002 | 0.1 | 1.5 | 0.02 | — | Example |
| 3B | 0.01 | 0.3 | 1 | 0.07 | — | |
| 3C | 0.007 | 0.1 | 2.2 | 0.05 | — | |
| 3D | 0.03 | 0.06 | 2 | 0.01 | Cu: 0.2, Ni: 0.1 | |
| 3E | 0.002 | 0.5 | 1.5 | 0.07 | — | |
| 3F | 0.08 | 0.1 | 2 | 0.01 | Cr: 0.05 | |
| 3G | 0.05 | 0.3 | 0.5 | 0.06 | Mo: 0.15 | |
| 3H | 0.15 | 0.3 | 0.7 | 0.02 | — | |
| 3I | 0.1 | 0.25 | 2.6 | 0.06 | Ca: 0.005 | |
| 3J | 0.003 | 0.25 | 2 | 0.01 | B: 0.001 | |
| 3K | 0.16 | 0.3 | 0.8 | 0.01 | — | |
| 3L | 0.25 | 0.5 | 2 | 0.012 | Mo: 0.3, B: 0.002, | |
| | | | | | Ti: 0.02 | |
| 3M | 0.04 | 0.07 | 3 | 0.01 | Sb: 0.01 | |
| 3N | 0.003 | 0.02 | 0.56 | 0.01 | — | Comparative |
| 3O | 0.003 | 0.04 | 0.34 | 0.065 | B: 0.002 | Example |
| 3P | 0.003 | 0.03 | 0.5 | 0.04 | — | |
| 3Q | 0.002 | 0.02 | 0.5 | 0.04 | — | |
| 3R | 0.008 | 0.05 | 0.75 | 0.09 | — | |
| 3S | 0.08 | 0.05 | 2 | 0.01 | Cr: 0.05 | |
| 3T | 0.008 | 0.09 | 1 | 0.09 | — | |
| 3U | 0.004 | 0.02 | 0.14 | 0.021 | — | |
| 3V | 0.08 | 0.07 | 2 | 0.01 | Ca: 0.005 | |
| 3W | 0.002 | 0.01 | 0.1 | 0.01 | Mo: 0.15 | |
| 3X | 0.01 | 0.02 | 0.45 | 0.01 | — | |
| 3Y | 0.12 | 0.02 | 1.5 | 0.015 | — | |
| 3Z | 0.08 | 0.06 | 1.5 | 0.03 | Sb: 0.01 | |

<Recrystallization annealing>
Atmosphere: 5 volume percent hydrogen+nitrogen (dew point: −35 degree centigrade)
Temperature: 750 degree centigrade
Holding time: 20 sec
   <Coating Condition>
Bath composition: Zn+0.14 mass percent Al (Fe saturation)
Bath temperature: 460 degree centigrade
Sheet temperature at the time of coating: 460 degree centigrade
Coating time: 1 sec
Concentration of oxygen in an atmosphere immediately before the coating: conditions described in Table 6 (the balance 5 volume percent hydrogen+nitrogen (dew point: −35 degree centigrade))

Obtained coating steel sheets contained 0.2 to 0.5 mass percent of Al and 0.5 to 2 mass percent of Fe in the coating layers. After the coating process, the galvannealing process was applied in air in an electric heater. The temperature rise speeds and galvannealing temperatures in the galvannealing process were the conditions described in Table 6.

Of each of obtained coating steel sheets, a cooling atmosphere from the recrystallization annealing to the coating, a thickness of a coating layer, a temperature rise speed, a temperature and a holding time in the galvannealing process, a content of Fe in the coating layer, a ratio of fine irregularity formed in an interface between the coating layer and a base steel sheet and a developed interfacial area ratio Sdr were investigated similarly to a method explained in the example 1. Furthermore, in addition to the evaluation of the abovementioned coating adhesion 1, evaluations of the coating adhesions 3 and 4 shown below were carried out. Results of these are shown in Table 6.

(Evaluation of the Coating Adhesion 3)

From each of the obtained steel sheets, a test piece having a width of40 mm and a length of 100 mm was cut out followed by adhering a cellophane tape (width: 24 mm, manufactured by Nichiban Co., Ltd.) at a position of a length 50 mm, a tape surface was bent inside by 90° followed by unbending, thereafter an amount of Zn adhered when the cellophane tape was peeled was measured as the number of counts by means of X-ray fluorescence analysis. The number of measured counts of Zn was compensated into the number of counts per unit length (1 m) of width of test piece and evaluated according to the following criteria.

<Evaluation Criteria of the Coating Adhesion 3>

◯◯: very good (number of counts: 500 or less)
◯: good (number of counts: more than 500 and 1000 or less)
Δ: fair (number of counts: more than 1000 and 3000 or less)
x: bad (number of counts: more than 3000)
   (Evaluation of the coating adhesion 4)

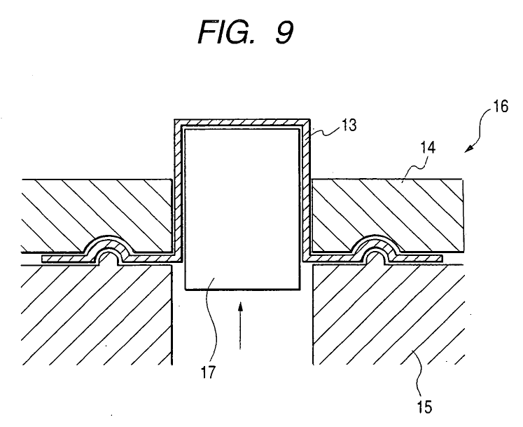

From each of the obtained steel sheets, a test piece having a width of 70 mm and a length of 150 mm was cut out, after dipping in rust-preventive oil 550 KH (manufactured by Nihon Parkerizing Co., Ltd.), left in air for 24 hr while standing obliquely, and thus obtained one was used as a test sample. A pressing test was carried out in which in a state where both ends of a test sample 13 were clamped between a die 14 and a wrinkle suppressor 15 that form a bead die 16 such as shown in FIG. 9, from a back surface side of the test sample 13, a punch 17 was pushed in to form a horseshoe shape. A surface of the die was polished with #1000 polishing paper and accretions were cleansed every time. A wrinkle suppressor force P was set at 12 kN and the punching speed was set at 100 mm/min. After the test, the test sample was slightly degreased, followed by adhering a cellophane tape (width: 24 mm, manufactured by Nichiban Corp.). An amount of Zn adhered to the cellophane tape when it was peeled was measured as the number of counts by X-ray fluorescence analysis, and evaluation was carried out according to the following criteria.

<Evaluation Criteria of the Coating Adhesion 4>

◯◯: very good (number of counts: 50 or less)
◯: good (number of counts: more than 50 and 100 or less)
Δ: fair (number of counts: more than 100 and 300 or less)

x: bad (number of counts: more than 300)

TABLE 6

| | | Concentration of | | | | | |
|---|---|---|---|---|---|---|---|
| | | oxygen in a cooling | | | | Galvannealed | |
| | | atmosphere until | | | | steel sheet | |
| | | the coating after | Galvannealing condition | | | Coating layer | |
| Test | | the recrystallization | Temperature | Galvannealing | Holding | | Content |
| sample | Steel | annealing | rise speed | temperature | time | Thickness | of Fe |
| No. | No. | (vol. %) | (° C./s) | (° C.) | (s) | (μm) | (mass %) |
| 1 | 3A | 0.002 | 20 | 480 | 15 | 6 | 11.0 |
| 2 | 3A | 0.002 | 25 | 490 | 10 | 3 | 10.5 |
| 3 | 3A | 0.002 | 25 | 490 | 23 | 6 | 12.9 |
| 4 | 3A | 0.001 | 30 | 520 | 25 | 14 | 11.0 |
| 5 | 3B | 0.001 | 25 | 490 | 10 | 7 | 9.2 |
| 6 | 3C | 0.001 | 30 | 510 | 15 | 11 | 10.5 |
| 7 | 3D | 0.002 | 25 | 490 | 10 | 9 | 10.2 |
| 8 | 3E | 0.002 | 30 | 520 | 9 | 7 | 10.2 |
| 9 | 3F | 0.003 | 25 | 490 | 15 | 9 | 11.5 |
| 10 | 3G | 0.002 | 20 | 470 | 25 | 6 | 10.9 |
| 11 | 3H | 0.002 | 35 | 520 | 15 | 6 | 11.9 |
| 12 | 3I | 0.002 | 20 | 460 | 10 | 4 | 8.9 |
| 13 | 3J | 0.002 | 25 | 490 | 15 | 7 | 9.9 |
| 14 | 3K | 0.002 | 20 | 460 | 30 | 7 | 10.5 |
| 15 | 3L | 0.002 | 25 | 480 | 20 | 6 | 10.8 |
| 16 | 3M | 0.002 | 35 | 560 | 4 | 5 | 9.8 |
| 17 | 3N | 0.002 | 20 | 520 | 20 | 12 | 12.5 |
| 18 | 3O | 0.002 | 20 | 520 | 25 | 10 | 12.3 |
| 19 | 3P | 0.002 | 20 | 490 | 15 | 6 | 11.5 |
| 20 | 3Q | 0.002 | 20 | 520 | 20 | 8 | 12.5 |
| 21 | 3R | 0.002 | 20 | 490 | 25 | 8 | 11.2 |
| 22 | 3S | 0.004 | 30 | 500 | 20 | 10 | 12.5 |
| 23 | 3T | 0.002 | 20 | 520 | 15 | 7 | 12.2 |
| 24 | 3U | 0.002 | 30 | 510 | 8 | 7 | 10.2 |
| 25 | 3V | 0.002 | 30 | 480 | 15 | 8 | 9.8 |
| 26 | 3W | 0.002 | 20 | 490 | 20 | 7 | 12.8 |
| 27 | 3X | 0.001 | 20 | 480 | 12 | 10 | 9.3 |
| 28 | 3Y | 0.002 | 35 | 490 | 12 | 7 | 10.3 |
| 29 | 3Z | 0.002 | 30 | 470 | 22 | 9 | 11.1 |
| 30 | 3D | 0.008 | 25 | 490 | 10 | 9 | 10.2 |

| | Galvannealed steel sheet | | | | | | |
|---|---|---|---|---|---|---|---|
| | Base steel | | Evaluation result | | | | |
| | sheet | | | Coating | | | |
| | Developed | Ratio of fine | | adhesion 1 | | | |
| Test | interfacial | irregularity in an | | Tensile | | | |
| sample | area ratio Sdr | interface | Coating | shear | Peeling | Coating | |
| No. | (%) | (%) | adhesion 3 | strength | mode | adhesion 2 | Note |
| 1 | 2.6 | 65 | ◯◯ | ◯◯ | ◯◯ | ◯◯ | Example |
| 2 | 2.3 | 30 | ◯◯ | ◯◯ | ◯◯ | ◯◯ | |
| 3 | 2.7 | 70 | ◯ | ◯◯ | ◯◯ | ◯ | |
| 4 | 2.6 | 60 | ◯ | ◯◯ | ◯◯ | ◯◯ | |
| 5 | 2.2 | 15 | ◯◯ | ◯◯ | ◯◯ | ◯◯ | |
| 6 | 2.4 | 40 | ◯ | ◯◯ | ◯◯ | ◯◯ | |
| 7 | 2.2 | 20 | ◯◯ | ◯◯ | ◯◯ | ◯◯ | |
| 8 | 2.5 | 50 | ◯◯ | ◯◯ | ◯◯ | ◯◯ | |
| 9 | 2.5 | 40 | ◯ | ◯◯ | ◯◯ | ◯◯ | |
| 10 | 2.6 | 60 | ◯◯ | ◯◯ | ◯◯ | ◯◯ | |
| 11 | 2.3 | 20 | ◯ | ◯◯ | ◯◯ | ◯◯ | |
| 12 | 2.1 | 15 | ◯◯ | ◯ | ◯◯ | ◯ | |
| 13 | 2.2 | 30 | ◯◯ | ◯◯ | ◯◯ | ◯◯ | |
| 14 | 2.1 | 20 | ◯◯ | ◯◯ | ◯◯ | ◯◯ | |
| 15 | 2.1 | 20 | ◯◯ | ◯◯ | ◯◯ | ◯◯ | |
| 16 | 2.1 | 20 | ◯◯ | ◯◯ | ◯◯ | ◯◯ | |
| 17 | 1.8 | 5 | Δ | Δ | ◯ | X | Comparative |
| 18 | 1.9 | 5 | Δ | ◯ | ◯ | X | Example |
| 19 | 1.8 | 5 | Δ | Δ | X | ◯ | |
| 20 | 1.8 | 5 | X | Δ | Δ | Δ | |
| 21 | 1.5 | 0 | Δ | X | X | Δ | |
| 22 | 1.5 | 0 | X | X | X | X | |
| 23 | 1.4 | 0 | Δ | X | Δ | ◯ | |
| 24 | 1.6 | 0 | X | X | X | Δ | |
| 25 | 1.5 | 0 | ◯ | Δ | Δ | ◯ | |
| 26 | 1.8 | 5 | Δ | ◯ | ◯◯ | Δ | |
| 27 | 1.5 | 0 | ◯◯ | Δ | Δ | ◯ | |
| 28 | 1.6 | 0 | X | X | X | Δ | |
| 29 | 1.6 | 0 | X | Δ | Δ | X | |
| 30 | 1.9 | 5 | Δ | Δ | Δ | Δ | |

From the evaluation results shown in Table 6, it is found that galvannealed steel sheets according to the invention (examples), in comparison with existing steel sheets (comparative examples), are largely heightened in the interfacial strength between the coating layer and the base steel sheet and improved in the coating adhesion.

### INDUSTRIAL APPLICABILITY

Since a galvannealed steel sheet according to the present invention is a galvannealed steel sheet that is remarkably excellent, in comparison with existing ones, in the coating adhesion at an interface between a coating layer and a base steel sheet, in the fields of automobiles, home electric appliances, construction materials and so on, there is no problem of peeling of the coating layer at processing, appearance after the processing is excellent, and sufficient rust resistance can be maintained. Accordingly, an industrially very useful effect in that the high mechanical strength and lighter weight can be attained for all shapes of components can be obtained.

1. A galvannealed steel sheet excellent in the coating adhesion characterized in that in an interface between a galvannealed layer and a base steel sheet on which the galvannealed layer is formed, an irregularity that has a depth of 10 nm or more at a pitch of 0.5 μm or less is present at least one per 5 μm of a length of the interface.

2. A galvannealed steel sheet excellent in the coating adhesion characterized in that a surface shape of a base steel sheet that is observed after a galvannealed layer is peeled has a developed interfacial area ratio Sdr measured by use of a high-pass filter with a cut-off wavelength of 0.5 μm of 2.0 percent or more.

3. The galvannealed steel sheet excellent in the coating adhesion according to claim 1 characterized in that the base steel sheet contains, by mass percent, 0.25 percent or less of C, 0.03 to 2.0 percent of Si and 0.005 to 0.07 percent of P and has a composition satisfying the following equation (1).
Note
[C]+[P]≦[Si] (1)
Here, [C], [P] and [Si], respectively, mean contents (mass percent) of C, P and Si in the base steel sheet.

4. The galvannealed steel sheet excellent in the coating adhesion according to claim 3 characterized in that in a stage immediately before a coating layer is adhered to the base steel sheet, in order that Si contained in the base steel sheet is not selectively oxidized on a surface, the base steel sheet is heat treated before the coating layer is adhered.

5. The galvannealed steel sheet excellent in the coating adhesion according to claim 3 characterized in that in a base steel immediate below the interface an oxide of silicon is contained.

6. The galvannealed steel sheet excellent in the coating adhesion according to claim 3 characterized in that the base steel sheet has a composition that further includes, by mass percent, 5 percent or less of Mn, 0.01 percent or less of S and 0.08 percent or less of Al.

7. The galvannealed steel sheet excellent in the coating adhesion according to claim 3 characterized in that the base steel sheet has a composition that further includes at least one kind selected from 0.2 percent or less of Ti, 0.2 percent or less of Nb and 0.2 percent or less of V, by mass percent.

8. A method of manufacturing a galvannealed steel sheet excellent in the coating adhesion characterized in that a base steel sheet that contains, by mass percent, 0.25 percent or less of C, 0.03 to 2.0 percent of Si and 0.005 to 0.07 percent of P and has a composition satisfying the following equation (1) is heat treated so that Si in the steel is not selectively surface oxidized, followed by cooling to a coating temperature in an atmosphere having an oxygen concentration of 0.005 volume percent or less, further followed by dipping the base steel sheet in a molten zinc coating bath to form a coating layer, still further followed by heating at a temperature rise speed of 20 degree centigrade/s or more to a temperature range of 460 to 600 degree centigrade and holding in the heating temperature range to apply a galvannealing process of the coating layer.
Note
[C]+[P]<[Si] (1)
Here, [C], [P] and [Si], respectively, mean contents (mass percent) of C, P and Si in the base steel sheet.

9. The method of manufacturing a galvannealed steel sheet excellent in the coating adhesion according to claim 8 characterized in that the base steel sheet has a composition that further includes, by mass percent, 5 percent or less of Mn, 0.01 percent or less of S and 0.08 percent or less of Al.

10. The method of manufacturing a galvannealed steel sheet excellent in the coating adhesion according to claim 8 characterized in that the base steel sheet has a composition that further includes at least one kind selected from 0.2 percent or less of Ti, 0.2 percent or less of Nb and 0.2 percent or less of V, by mass percent and the temperature rise speed and a content of Si in the base steel sheet satisfy the following equation (2).
Note
ST≧3.25/[Si] (2)
Here, in the equation, ST designates a temperature rise speed (degree centigrade/s) and [Si] designates a content (mass percent) of Si in the steel sheet.

11. The galvannealed steel sheet excellent in the coating adhesion according to claim 2 characterized in that the base steel sheet contains, by mass percent, 0.25 percent or less of C, 0.03 to 2.0 percent of Si and 0.005 to 0.07 percent of P and has a composition satisfying the following equation (1).
Note
[C]+[P]≦[Si] (1)
Here, [C], [P] and [Si], respectively, mean contents (mass percent) of C, P and Si in the base steel sheet.

12. The galvannealed steel sheet excellent in the coating adhesion according to claim 11 characterized in that in a stage immediately before a coating layer is adhered to the base steel sheet, in order that Si contained in the base steel sheet is not selectively oxidized on a surface, the base steel sheet is heat treated before the coating layer is adhered.

13. The galvannealed steel sheet excellent in the coating adhesion according to claim 11 characterized in that in a base steel immediate below the interface an oxide of silicon is contained.

14. The galvannealed steel sheet excellent in the coating adhesion according to claim 11 characterized in that the base steel sheet has a composition that further includes, by mass percent, 5 percent or less of Mn, 0.01 percent or less of S and 0.08 percent or less of Al.

15. The galvannealed steel sheet excellent in the coating adhesion according to claim 11 characterized in that the base steel sheet has a composition that further includes at least one kind selected from 0.2 percent or less of Ti, 0.2 percent or less of Nb and 0.2 percent or less of V, by mass percent.

16. The method of manufacturing a galvannealed steel sheet excellent in the coating adhesion according to claim 9 characterized in that the base steel sheet has a composition that further includes at least one kind selected from 0.2 percent or less of Ti, 0.2 percent or less of Nb and 0.2 percent or less of V, by mass percent and the temperature rise speed and a content of Si in the base steel sheet satisfy the following equation (2).
Note
ST>3.25/[Si] (2)
Here, in the equation, ST designates a temperature rise speed (degree centigrade/s) and [Si] designates a content (mass percent) of Si in the steel sheet.
